(19) United States
(12) Patent Application Publication
(10) Pub. No.: US 2011/0271998 A1
(43) Pub. Date: Nov. 10, 2011

(54) SOLAR CELL MODULE AND MANUFACTURING METHOD THEREOF

(76) Inventors: Katsuyuki Naitoh, Osaka (JP); Hiroshi Nishiyama, Osaka (JP)

(21) Appl. No.: 13/145,027

(22) PCT Filed: Jan. 16, 2010
(86) PCT No.: PCT/JP2010/050217

§ 371 Date: Jul. 18, 2011

(30) Foreign Application Priority Data
Jan. 16, 2009 (JP) 2009-007610

(51) Int. Cl. H01L 31/05; H01L 31/18

(52) U.S. Cl. 136/244; 438/57; 257/E31.001

(57) ABSTRACT

A solar cell module that causes no cost increase and prevents an electrical contact between an Ag back-side conducting layer and a connection portion between an extraction wire and a draw wire. According to an embodiment of the present invention, in a solar cell module including a solar cell 55 composed of a surface substrate, a light-receiving side conducting layer, a semiconductor layer and a back-side conducting layer and having a wiring structure in which an extraction wire 60, 61 for extraction of current is connected to the back-side conducting layer, and a draw wire 62, 63 for outputting the current to the outside is connected to the extraction wire 60, 61, an isolation member 59 is disposed between a portion where the extraction wire 60, 61 and the draw wire 62, 63 are connected and the back-side conducting layer. The isolation member 59 is formed to have a polygonal, circular or elliptic shape having an area larger is than a solder wetting region in the connection portion between the extraction wire 60, 61 and the draw wire 62, 3.

### TECHNICAL FIELD

The present invention relates to a solar cell module including a solar cell composed of a surface substrate, a light-receiving side conducting layer, a semiconductor layer and a back-side conducting layer, and having a wiring structure in which an extraction wire for extraction of current is connected to the back-side conducting layer, and a draw wire for outputting the current to the outside is connected to the extraction wire, and a method of manufacturing such a solar cell module.

### BACKGROUND ART

Solar power generation systems for generating solar power in which solar cell modules, each including a plurality of solar cell strings arranged in a matrix, are placed on the roof of buildings or the like are beginning to come into wide use. In such a solar cell power generation system, each solar cell module is provided with a terminal box for enabling an electrical connection with another solar cell module placed adjacent to the solar cell module.

An example configuration of a solar cell string constituting a conventional solar cell module is shown in FIGS. 6(a) and 6(b) and FIG. 7. FIGS. 6(a) and 6(b) are illustrative diagrams showing two scenes of a manufacturing process thereof, and FIG. 7 is an illustrative diagram showing a step of laminating and sealing a solar cell string. The example configuration of a solar cell string shown in FIGS. 6 and FIG. 7 is also described in Patent Document 1.

A solar cell 115 is formed by laminating, on a light-transmitting insulating substrate 111 made of glass or the like, although not shown in the diagrams, a light-receiving side conducting layer made of a transparent conductive film (TCO: Transparent Conductive Oxide), a photoelectric conversion semiconductor layer, and an Ag back-side conducting layer which is a back face electrode film in this order using a vacuum apparatus or the like.

The solar cell 115 thus formed has an elongated strip shape as shown in FIG. 6(a). A solar cell string 116 in which a plurality of solar cells 115 are connected in series is configured by connecting the light-receiving side conducting layer (transparent electrode film) of one of each two adjacent solar cells 115 and the Ag back-side conducting layer (back face electrode film) of the other solar cell to each other.

In other words, for high voltages, the light-receiving side conducting layer, the semiconductor layer and the back-side conducting layer are each cut by laser as necessary. Furthermore, laser processing is also used for cutting to form several groups of solar cells connected in series, and each group of solar cells connected in series obtained after cutting is called a string (solar cell string) as described above.

A P-type electrode terminal portion 117 is formed on the solar cell 115 located at one end of the solar cell string 116, and an N-type electrode terminal portion 118 is formed on the end of the Ag back-side conducting layer (back face electrode film) of the solar cell 115 located on the other end of the solar cell string 116. The P-type electrode terminal portion 117 and the N-type electrode terminal portion 118 serve as electrode extraction portions.

A filler sheet 119 and a glass non-woven sheet 112 are placed on the solar cell string 116 so as to extend between a center portion of the P-type electrode terminal portion 117 and a center portion of the N-type electrode terminal portion 118. The filler sheet 119 and the glass non-woven sheet 112 are placed such that they do not overlap the P-type electrode terminal portion 117 and the N-type electrode terminal portion 118. As the filler sheet 119, it is preferable to use a film compatible with a sealant.

On the other hand, a 120 μm thick positive extraction wire (positive electrode current collecting portion) 120 made of a copper foil and called bus bar is electrically and mechanically bonded to the P-type electrode terminal portion 117. Likewise, a 120 μm thick negative extraction wire (negative electrode current collecting portion) 121 made of a copper foil and called bus bar is electrically and mechanically bonded to the entire face of the N-type electrode terminal portion 118. As a means for bonding these, soldering or a conductive paste can be used, for example.

On the filler sheet 119, a positive draw wire (positive electrode lead wire) 122 and a negative draw wire (negative electrode lead wire) 123 that are made of flat cables and have a thickness of 160 μm are disposed in line (or parallel, i.e., disposed offset in the width direction), with their tips opposing each other. FIGS. 6 show an example in which the wires are disposed in line.

An end of the positive draw wire 122 is connected to a center portion of the positive extraction wire 120. The other end of the positive draw wire 122 is positioned in a substantially center portion of the solar cell string 116 and is bent so as to stand upright from the face of the solar cell string 116 (for example, perpendicularly with respect to the face) to serve as an output lead portion 122a. Likewise, an end of the negative draw wire 123 is connected to a center portion of the negative extraction wire 121. The other end of the negative draw wire 123 is positioned in a substantially center portion of the solar cell string 116 and is bent so as to stand upright from the face of the solar cell string 116 (for example, perpendicularly with respect to the face) to serve as an output lead portion 123a.

The positive draw wire 122 and the negative draw wire 123 extend across a plurality of solar cells 115, but the filler sheet 119 and the glass non-woven sheet 112 are present between the wires and the solar cells 115, and therefore the solar cells 115 will not be short-circuited.

In this state, as shown in FIG. 7, a sealing film 124 and a back film 125 serving as a back face protection member for weather resistance and high insulation are laminated and sealed on the entire face of the solar cell string 116, with the output lead portions 122a and 123a of the positive draw wire 122 and the negative draw wire 123 being drawn out from openings 124a and 125a. The sealing film 124 is preferably a thermoplastic polymer film, and in particular, it is optimal to use a film made of EVA (ethylene vinyl acetate resin) or PVB (polyvinyl butyral resin). The back film 125 is preferably, in order to ensure moisture resistance, a film including a moisture resistant layer such as a three-layer structure film of PET/Al/PET (PET: polyethylene terephthalate) or a three-layer structure film of PVF/Al/PVF (PVF: polyvinyl fluoride resin film).

In the solar cell string 116 thus configured, a terminal box (not shown) is attached and electrically connected to the output lead portions 122a and 123a of the positive draw wire 122 and the negative draw wire 123 protruding upward from the openings 125a of the back film 125.

In order to extract current generated by a plurality of integrated solar cells 115 from the positive extraction wire 120 and the negative extraction wire 121, the positive draw wire 122 and the negative draw wire 123 are wired and disposed so as to extend across the solar cells 115 to positions corresponding to the openings 125a of the back film 125. In this case, it is necessary to ensure insulation between the wires and the solar cells 115. In Patent Document 1 described above, insulation is ensured by disposing the filler sheet 119 and the glass non-woven sheet 112 one above the other between the wires and the solar cells.

### Prior Art Document

### Patent Document

Patent Document 1: JP 2001-77392 A

### SUMMARY OF INVENTION

### Problems to be Solved by the Invention

The positive extraction wire 120 and the negative extraction wire 121 that are respectively connected to the light-receiving side conducting layer and the Ag back-side conducting layer of the solar cells 115 are connected to the P-type electrode terminal portion 117 and the N-type electrode terminal portion 118, respectively, in order to supply power to the positive draw wire 122 and the negative draw wire 123. Accordingly, each extraction wire 120, 121 requires a means for obtaining an electrical conduction with the draw wire 122, 123. Usually, soldering is generally performed as a means for obtaining an electrical connection.

In order to efficiently carry out soldering, the extraction wires 120 and 121 and the draw wires 122 and 123 are each covered with solder, and in some cases, solder is supplied to the connection portions as well.

In order to connect the extraction wires 120 and 121 to the light-receiving side conducting layer and the Ag back-side conducting layer, respectively, and connect the draw wires 122 and 123 to the extraction wires 120 and 121, respectively, an end of the draw wire 122, 123 is overlapped with a center portion in the lengthwise direction of the extraction wire 120, 121, and the T-shaped laminated intersection is soldered.

The soldering is carried out above the Ag back-side conducting layer. However, a situation can occur in which molten solder flows onto the Ag back-side conducting layer during solder connection, and the connection portion between the extraction wire 120, 121 and the draw wire 122, 123 is attached to the Ag back-side conducting layer. As a result, a problem occurs in that when the draw wire 122, 123 undergoes thermal expansion/contraction due to changes in ambient temperature, the solar cell structure is separated at the portion to which the connection portion has been attached, causing damage such as progression of separation and reducing reliability.

In the thin film solar cell module described in Patent Document 1 mentioned above, a filler sheet 119 and a glass nonwoven sheet 112 are disposed one above the other between the positive draw wire 122 and the negative draw wire 123 and the solar cells 115 for the purpose of ensuring insulation between the wires and the solar cells, and not for protecting the Ag back-side conducting layer from attachment of the connection portion due to molten solder. In other words, Patent Document 1 does not give consideration to prevent damage to the conducting layers to which attention needs to be given when the extraction wire and the draw wire are soldered.

It is possible to solve this problem using the configuration of Patent Document 1 mentioned above. Specifically, by disposing the filler sheet 119 and the glass non-woven sheet 112 one above the other between the solar cell 115 and the intersection between the draw wire 122, 123 and the extraction wire, it is possible to prevent solder from flowing into the back-side conducting layer. However, the configuration of Patent Document 1 mentioned above requires use of a glass non-woven sheet and a filler sheet. This is to produce an effect to cause the glass non-woven sheet 112 to have good permeability and the same refractive index as that of the filler sheet 119 and to become transparent, and the glass non-woven sheet and the filler sheet are superfluous from the viewpoint of avoiding contact between the Ag back-side conducting layer and the intersection. This leads to unnecessary cost increase, and therefore it is not desirable to use the combination of a glass non-woven sheet and a filler sheet.

The present invention has been conceived in view of the above points, and it is an object of the present invention to provide a solar cell module in which contact between the Ag back-side conducting layer and the connection portion between the extraction wire and the draw wire can be prevented without causing a cost increase, and a method of manufacturing such a solar cell module.

### Means for Solving the Problems

In order to solve the problems described above, a solar cell module according to the present invention is a solar cell module including a solar cell composed of a surface substrate, a light-receiving side conducting layer, a semiconductor layer and a back-side conducting layer and having a wiring structure in which an extraction wire for extraction of current is connected to the back-side conducting layer, and a draw wire for outputting the current to the outside is connected to the extraction wire, wherein an isolation member is disposed between a portion where the extraction wire and the draw wire are connected and the back-side conducting layer. With this configuration, when the connection portion between the draw wire and the extraction wire is soldered, solder will not come into contact with the Ag back-side conducting layer, and therefore the problem of attachment of the connection portion between the extraction wire and the draw wire to the Ag back-side conducting layer can be solved.

In this case, it is preferable that isolation member is a tape having a sticky face at least on onside thereof. By doing so, the position of the isolation member can be fixed, improving operability. Also, the position of the intersection between the draw wire and the extraction wire on which soldering is performed can be confirmed, further improving operability.

Also, it is desirable that the isolation member has a thickness of 120 μm or less. If the thickness of the isolation member is 120 μm or more, and the extraction wire has a thickness of 120 μm and the draw wire has a thickness of 160 μm, for example, the total thickness will be 400 μm (0.4 mm). As a result, the draw wire becomes closer to the back face protection member laminated thereon, causing an additional problem in that insulation cannot be ensured between the wire and the metal layer laminated on the back face protection member. Accordingly, it is desirable that the thickness of the isolation member is as small as possible, and at least 120 μm or less.

Also, it is preferable that the isolation member has a heat resistant temperature of 180° C. or more. In this case, the isolation member itself will not thermally damaged by heat application during soldering.

Also, it is preferable that the isolation member is formed to have a polygonal, circular or elliptic shape having an area larger than a solder wetting region at the portion where the extraction wire and the draw wire are solder-connected. By forming the isolation member to have such a shape and area, it is possible to reliably prevent molten solder from coning into contact with the Ag back-side conducting layer.

Also, the isolation member may be configured to include a plurality of isolation members that are overlapped. By doing so, even if a need arises to add an isolation member for some reason (for example, a sticky isolation member has been disposed in a wrong position), it is possible to dispose a new isolation member on the already disposed isolation member.

A method of manufacturing a solar cell module according to the present invention is a method of manufacturing a solar cell module including a solar cell composed of a surface substrate, a light-receiving side conducting is layer, a semiconductor layer and a back-side conducting layer and having a wiring structure in which an extraction wire for extraction of current is connected to the back-side conducting layer, and a draw wire for outputting the current to the outside is connected to the extraction wire, the method including the steps of disposing an isolation member on the back-side conducting layer of the solar cell corresponding to a portion where the extraction wire and the draw wire are to be connected; and disposing the extraction wire so as to extend along the disposed isolation member to electrically connect to the back-side conducting layer, disposing the draw wire on the extraction wire in an overlapped manner, and electrically connecting the draw wire to the extraction wire. With this configuration, when the connection portion between the draw wire and the extraction wire is soldered, solder will not come into contact with the Ag back-side conducting layer, and therefore the problem of attachment of the connection portion between the extraction wire and the draw wire to the Ag back-side conducting layer can be solved.

### Effects of the Invention

Because the present invention has been configured as described above, when the draw wire and the extraction wire are soldered, solder will not come into contact with the Ag back-side conducting layer, and thus the problem of attachment of the connection portion between the extraction wire and the draw wire to the Ag back-side conducting layer can be solved. In other words, even when the draw wire undergoes thermal expansion/contraction due to changes in ambient temperature, the connection portion will not be attached to the Ag back-side conducting layer, and therefore separation from the solar cell structure will not occur and the reliability of the solar cell module will not be reduced.

### BRIEF DESCRIPTION OF DRAWINGS

FIG. 1 show an example configuration of a solar cell module according to Embodiment 1 of the present invention, with FIGS. 1(a) and 1(b) showing two scenes of a manufacturing process thereof.

FIG. 2 is an illustrative diagram showing a step of laminating and sealing a solar cell string of the solar cell module according to Embodiment 1 of the present invention.

FIG. 3 is a cross-sectional view taken along the line D-D shown in FIG. 1.

FIG. 4 is a perspective view showing an example configuration of a solar cell module according to Embodiment 2 of the present invention.

FIG. 5 is a cross-sectional view taken along the line E-E shown in FIG. 4.

FIGS. 6 show an example configuration of a conventional solar cell string, with FIGS. 6(a) and 6(b) showing two scenes of a manufacturing process thereof.

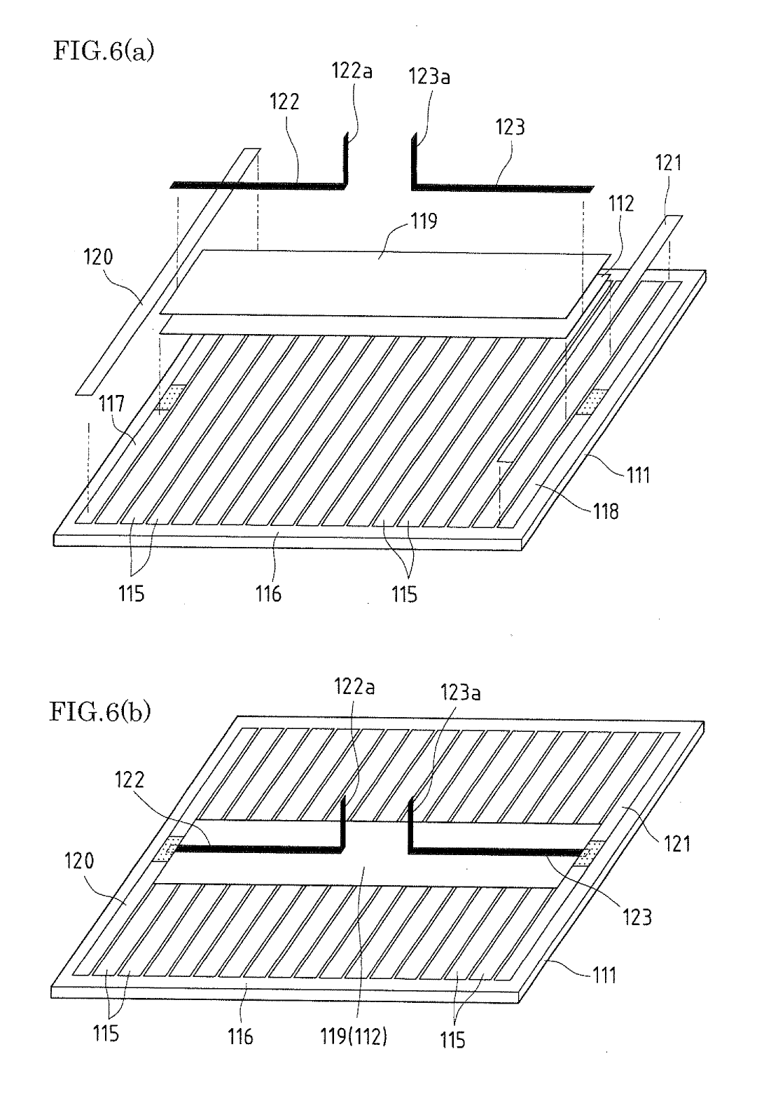

FIG. 7 is an illustrative diagram showing a step of laminating and sealing a conventional solar cell string.

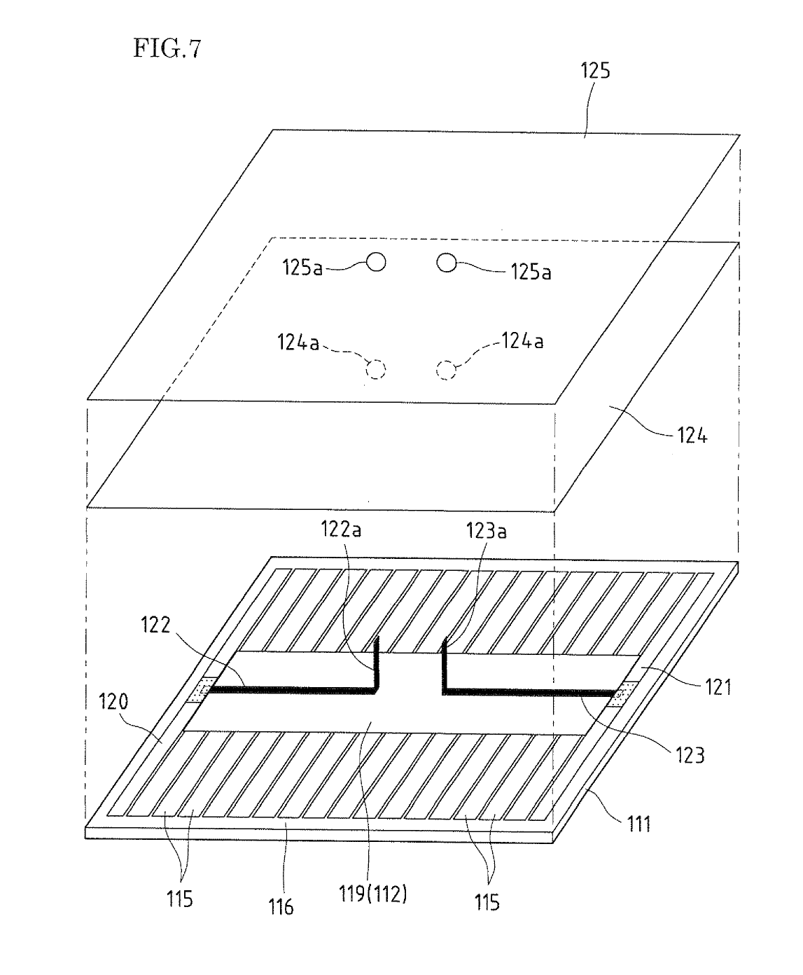

### MODES FOR CARRYING OUT THE INVENTION

Hereinafter, embodiments of the present invention will be described with reference to the drawings.

### Embodiment 1

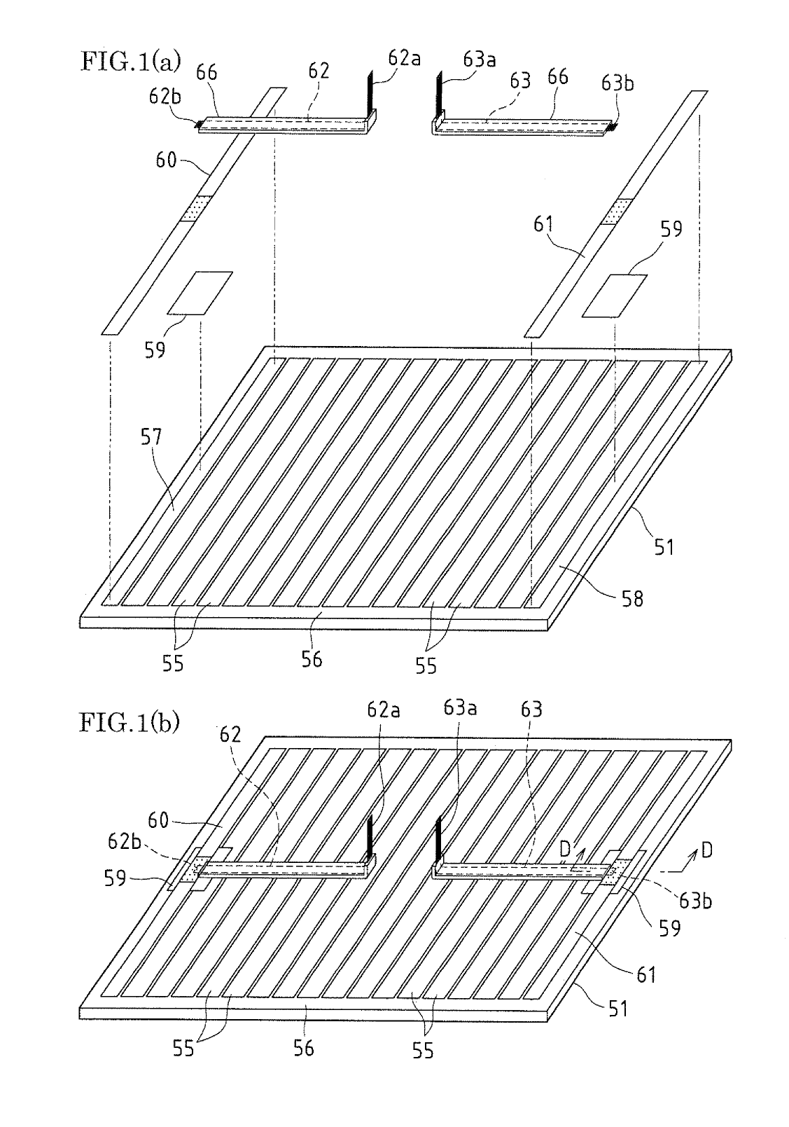

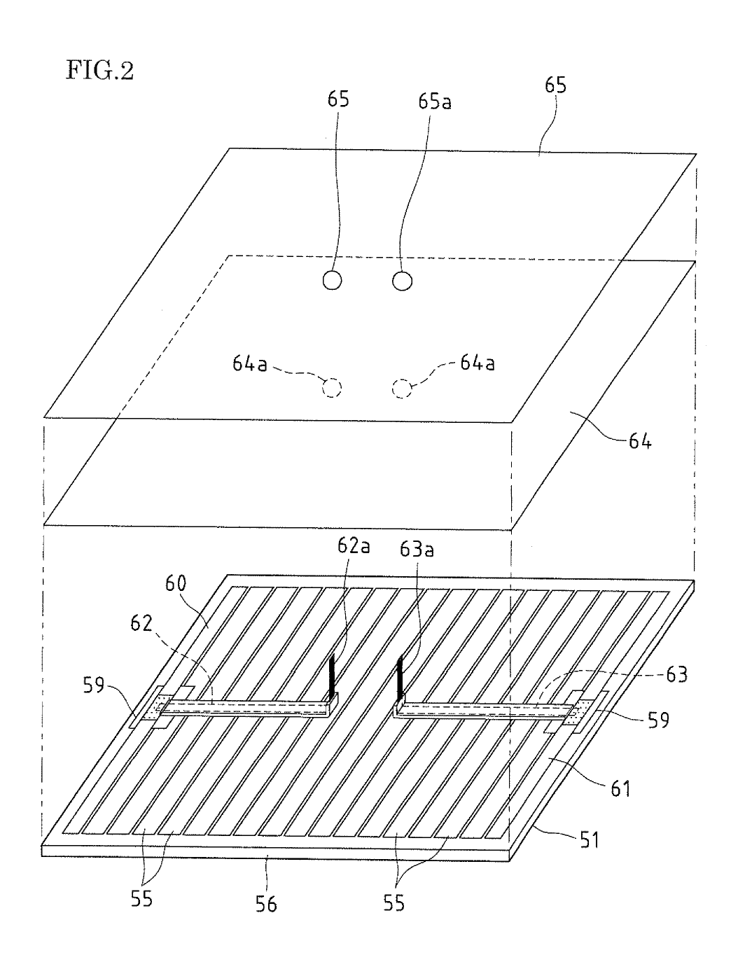

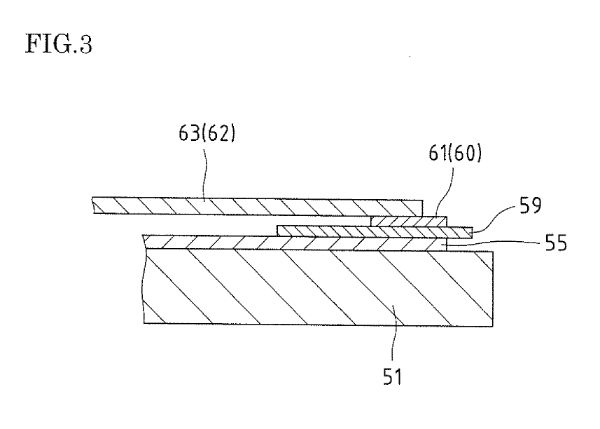

FIGS. 1(a) and 1(b) to FIG. 3 show an example configuration of a solar cell module according to Embodiment 1. FIGS. 1(a) and 1(b) are illustrative diagrams showing two scenes of a manufacturing process thereof, FIG. 2 is an illustrative diagram showing a step of laminating and sealing a solar cell string, and FIG. 3 is a cross-sectional view taken along the line D-D shown in FIG. 1. FIG. 3 is a cross-sectional view of a connection portion between a negative extraction wire 61 and a negative draw wire 63, but because the cross section of a connection portion between a positive extraction wire 60 and a positive draw wire 62 is the same, reference numerals corresponding to the positive extraction wire 60 and the positive draw wire 62 are shown in parentheses in the drawing.

A solar cell 55 is formed by laminating, on a light-transmitting insulating substrate (surface substrate) 51 made of glass or the like, although not shown in the diagrams, a light-receiving side conducting layer made of a transparent conductive film (TCO: Transparent Conductive Oxide), a photoelectric conversion semiconductor layer, and an Ag back-side conducting layer which is a back face electrode film in this order using a vacuum apparatus or the like. The light-transmitting insulating substrate can be made of glass or a heat resistant resin such as polyimide. The transparent electrode film can be made of SnO₂, ZnO, ITO or the like. The photoelectric conversion semiconductor layer can be made of a silicon-based photoelectric conversion film such as amorphous silicon or microcrystalline silicon, or a compound-based photoelectric conversion film such as CdTe or CuInSe₂.

The solar cell 55 thus configured has an elongated strip shape as shown in FIG. 1(a). A solar cell string 56 in which a plurality of solar cells 55 are connected in series is configured by connecting the light-receiving side conducting layer (transparent electrode film) of one of each two adjacent solar cells 55 and the Ag back-side conducting layer (back face electrode film) of the other solar cell to each other.

In other words, for high voltages, the light-receiving side conducting layer, the semiconductor layer and the back-side conducting layer are each cut by laser as necessary. Furthermore, laser processing is also used for cutting to form several groups of solar cells connected in series, and each group of solar cells connected in series obtained after cutting is called a string (solar cell string) as described above.

Then, a P-type electrode terminal portion 57 is formed on the solar cell 55 located at one end of the solar cell string 56, and an N-type electrode terminal portion 58 is formed on the end of the Ag back-side conducting layer of the solar cell 55 located on the other end of the solar cell string 56. The P-type electrode terminal portion 57 and the N-type electrode terminal portion 58 serve as electrode extraction portions.

A 120 μm thick positive extraction wire (positive electrode current collecting portion) 60 made of a copper foil and called bus bar is electrically and mechanically bonded to the P-type electrode terminal portion 57, and a 120 μm thick negative extraction wire (negative electrode current collecting portion) 61 made of a copper foil and called bus bar is electrically and mechanically bonded to the N-type electrode terminal portion 58. As a means for bonding these, soldering or a conductive paste (Ag paste) can be used, for example.

In the above-described configuration, a positive draw wire (positive electrode lead wire) 62 and a negative draw wire (negative electrode lead wire) 63 that are made of flat cables covered with an insulating film 66 are disposed in line (or parallel, i.e., disposed offset in the width direction) on the solar cell string 56, with their tips opposing each other. FIGS. 1 show an example in which the wires are disposed in line.

An exposed end 62b of the positive draw wire 62 is connected to a center portion of the positive extraction wire 60 by soldering. In order to prevent molten solder from flowing and coming into contact with the Ag back-side conducting layer during soldering, an isolation member 59 is provided between a portion where the positive extraction wire 60 and the positive draw wire 62 are connected and the Ag back-side conducting layer (see FIG. 3). The other end of the positive draw wire 62 is positioned in a substantially center portion of the solar cell string 56 and is bent so as to stand upright from the face of the solar cell string 56 (for example, perpendicularly with respect to the face) to serve as an output lead portion 62a.

Likewise, an exposed end 63b of the negative draw wire 63 is connected to a center portion of the negative extraction wire 61 by soldering. In order to prevent molten solder from flowing and coming into contact with the Ag back-side conducting layer during soldering, an isolation member 59 is provided between a portion where the negative extraction wire 61 and the negative draw wire 63 are connected and the Ag back-side conducting layer (see FIG. 3). The other end of the negative draw wire 63 is positioned in a substantially center portion of the solar cell string 56 and is bent so as to stand upright from the face of the solar cell string 56 (for example, perpendicularly with respect to the face) to serve as an output lead portion 63a.

The positive draw wire 62 and the negative draw wire 63 extend across a plurality of solar cells 55, but the draw wires 62 and 63 are entirely covered with the insulating film 66, and therefore the solar cells 55 will not be short-circuited.

In this state, as shown in FIG. 2, a sealing insulating film 64 and a back film 65 serving as a back face protection member for weather resistance and high insulation are laminated and sealed on the entire face of the solar cell string 56, with the output lead portions 62a and 63a of the positive draw wire 62 and the negative draw wire 63 being drawn out from openings 64a and 65a. The sealing insulating film 64 can be any film as long as it has good adhesion to the back film 65, the insulating film 66 and the solar cells 55 and superior long-term weather resistance, such as PVB or silicone, but in particular, it is most preferable to use a film made of EVA (ethylene vinyl acetate resin) because it has shown satisfactory performance as a film for solar cells. In particular, by selecting films having good adhesion to each other as the sealing insulating film 64 and the insulating film 66, the water resistance of the solar cell string can be improved. The back film 65 is preferably a three layer structure film including a moisture resistant layer such as a PET/Al/PET film (PET: polyethylene terephthalate). As for the thicknesses of these films, for example, when the insulating film 66 has a thickness of 50 μm and the sealing insulating film 124 has a thickness of 600 μm, the back film 65 has a thickness of 100 μm.

In the solar cell string 56 thus configured, a terminal box (not shown) is attached and electrically connected to the output lead portions 62a and 63a of the positive draw wire 62 and the negative draw wire 63 protruding upward from the openings 65a of the back film 65.

The arrangement of the isolation member 59, which is a feature of the present invention, will be described next in detail.

As described above, the isolation member 59 is provided between the portion where the positive extraction wire 61 and the positive draw wire 62 are connected, and the Ag back-side conducting layer, and between the portion where the negative extraction wire 61 and, the negative draw wire 63 are connected and the Ag back-side conducting layer, in order to prevent molten solder from flowing and coming into contact with the Ag back-side conducting layer during soldering.

As the isolation member 59, it is convenient to use a tape having a sticky face on one side thereof. With a tape having a sticky face on one side thereof, it is sufficient to attach the tape to the Ag back-side conducting layer, and thus it can be easily disposed. Moreover, once the isolation member 59 has been attached, the isolation member 59 will not shift out of position, and therefore it can be used as a positioning mark when the extraction wire 60, 61 and the draw wire 62, 63 are overlapped for soldering.

As the isolation member 59, specifically, a polyimide tape can be used. It is preferable to use, for example, No. 360 UL available from Nitto Denko Corporation.

Also, usually, with a polyimide tape having a maximum allowable temperature of 180° C., even when SnAgCu solder having a melting point of approximately 220° C. is used, the isolation member 59 itself will not be damaged by soldering operation, and thus such a polyimide tape is preferable to achieve an object of the present invention.

Also, the outer shape of the isolation member 59 can be any shape such as a polygonal shape, a circular shape or an elliptic shape. With any shape, the effects of the present invention can be obtained. In other words, the shape of the isolation member can be determined according to the shape into which molten solder spreads. As an example, in Embodiment 1, the isolation member has a square or rectangular shape.

Furthermore, the sealing insulating film 64 and the back film 65 serving as a back face protection member and covering a portion (connection portion) in which the isolation member 59, the extraction wire 60, 61 and the draw wire 62, 63 are laminated will protrude at that portion because the films are raised by that portion. In this case, if there is a projection of the molten solder, there is a possibility that the projection portion might damage the sealing insulating film 64 and the back film 65. Accordingly, it is desirable that the thickness of the isolation member 59 is as small as possible.

For example, if the thickness of the isolation member 59 is 120 μm or more, and the extraction wire 60, 61 has a thickness of 120 μm and the draw wire 62, 63 has a thickness of 160 μm, the total thickness will be 400 μm (0.4 mm). As a result, the draw wire 62, 63 becomes closer to the back film 65 laminated thereon, causing another problem in that insulation cannot be ensured between the wire and the metal layer (Al) laminated on the back film 65. Accordingly, it is desirable that the thickness of the isolation member 59 is as small as possible, and at least 120 μm or less.

In the present embodiment, as the sealing insulating film 64, a 0.4 mm thick EVA sheet available from Mitsui Chemicals Fabro, Inc. is used. Specifically, when the thickness of the substrate of a polyimide tape used as the isolation member 59 is 50 μm, insulation between the draw wire 62, 63 and the back film 65 at the connection portion can be ensured (specifically, when the total (330 μm) of the isolation member (50 μm), the extraction wire (120 μm) and the draw wire (160 μm) is subtracted from the thickness (400 μm) of the EVA sheet, a thickness of 70 μm can be ensured as the EVA thickness between the back film 65 and the draw wire 62, 63 at the connection portion).

The present inventors conducted a dielectric strength test with application of a voltage of 8 kV using the solar cell module having the above configuration and thickness, and have confirmed that no problem occurred,

### Embodiment 2

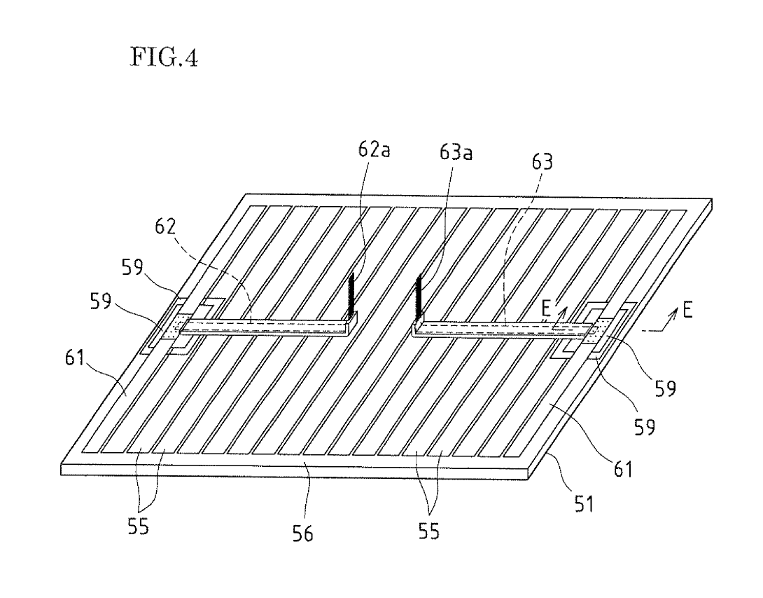

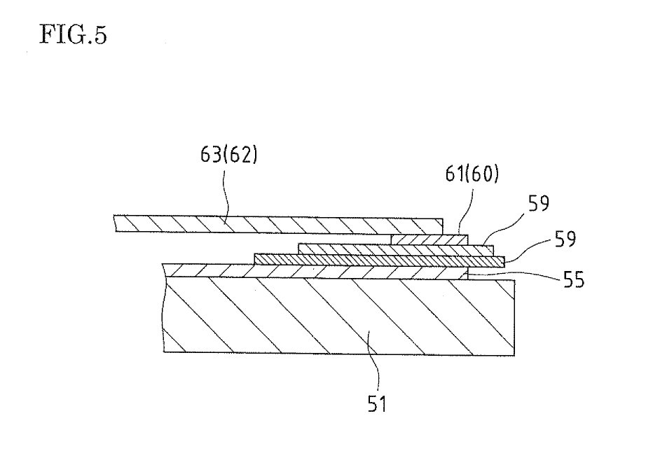

FIGS. 4 and 5 are perspective views showing Embodiment 2 of the present invention that has a structure in which two isolation members 59 are overlapped. Other than this, Embodiment 2 has the same structure as Embodiment 1 described above. FIG. 5 is a cross-sectional view of a connection portion between a negative extraction wire 61 and a negative draw wire 63, but because the cross section of a connection portion between a positive extraction wire 60 and a positive draw wire 62 is the same, reference numerals corresponding to the positive extraction wire 60 and the positive draw wire 62 are shown in parentheses in the drawing.

As described in Embodiment 1 above, when the isolation member 59 has a sticky face on one side, it is easy to dispose and fix the isolation member 59 in a position in which an intersection (connection portion) of the extraction wire 60, 61 and the draw wire 62, 63 are soldered, but there is a possibility that the isolation member 59 might be attached to a wrong position. In this case, when the isolation member 59 is detached and again attached, the Ag back-side conducting layer might be separated during detachment of the isolation member 59. To address this, another isolation member 59 may be attached on the isolation member 59 attached first. By doing so, the isolation member 59 can be attached to the correct position without damaging the Ag back-side conducting layer, and thus isolation from molten solder which is an object of the present invention can be reliably achieved.

In the above embodiments, the electrode arrangement in the solar cell string 56 is merely an example, and the present invention is not limited to the arrangement described above. For example, the positive draw wire 62 and the negative draw wire 63 may be disposed at a position closer to one of the ends of the solar cell string 56, rather than the center portion of the solar cell string 56, and the wires may not necessarily be drawn out to the center portion. In other words, the positive draw wire 62 and the negative draw wire 63 may be disposed such that the output lead portions 62a and 63a protrude upward from near the positive extraction wire 60 and the negative extraction wire 61.

### INDUSTRIAL APPLICABILITY

The present invention can prevent contact between the Ag back-side conducting layer and the connection portion between the extraction wire and the draw wire, and therefore can provide a highly reliable solar cell module that causes no damage to the conducting layers and no cost increase, and a method of manufacturing such a solar cell module. Accordingly, the present invention is useful in the field of solar power generation systems.

### DESCRIPTION OF REFERENCE NUMERALS

51 Light-Transmitting Insulating Substrate

55 Solar Cell

56 Solar Cell String (Thin Film Solar Cell String)

57 P-Type Electrode Terminal Portion

58 N-Type Electrode Terminal Portion

59 Isolation Member

60 Positive Extraction Wire (Positive Electrode Current Collecting Portion)

61 Negative Extraction Wire (Negative Electrode Current Collecting Portion)

62 Positive Draw Wire (Positive Electrode Lead Wire)

63 Negative Draw Wire (Negative Electrode Lead Wire)

62a, 63a Output Lead Portion

64 Sealing Insulating Film

65 Back Film

64a, 65a Opening

1-7. (canceled)

8. A solar cell module including a solar cell composed of a surface substrate, a light-receiving side conducting layer, a semiconductor layer and a back-side conducting layer and having a wiring structure in which an extraction wire for extraction of current is connected to the back-side conducting layer, and a draw wire for outputting the current to the outside is connected to the extraction wire,
wherein an isolation member is disposed between a portion where the extraction wire and the draw wire are connected and the back-side conducting layer.

9. The solar cell module according to claim 8,
wherein the isolation member has a sticky face on one side.

10. The solar cell module according to claim 8,
wherein the isolation member has a thickness of 120 μm or less.

11. The solar cell module according to claim 9,
wherein the isolation member has a thickness of 120 μm or less.

12. The solar cell module according to claim 8,
wherein the isolation member has a heat resistant temperature of 180° C. or more.

13. The solar cell module according to claim 9,
wherein the isolation member has a heat resistant temperature of 180° C. or more.

14. The solar cell module according to claim 10,
wherein the isolation member has a heat resistant temperature of 180° C. or more.

15. The solar cell module according to claim 11,
wherein the isolation member has a heat resistant temperature of 180° C. or more.

16. The solar cell module according to claim 8,
wherein the isolation member is formed to have a polygonal, circular or elliptic shape having an area larger than a solder wetting region at the portion where the extraction wire and the draw wire are solder-connected.

17. The solar cell module according to claim 9,
wherein the isolation member is formed to have a polygonal, circular or elliptic shape having an area larger than a solder wetting region at the portion where the extraction wire and the draw wire are solder-connected.

18. The solar cell module according to claim 10,
wherein the isolation member is formed to have a polygonal, circular or elliptic shape having an area larger than a solder wetting region at the portion where the extraction wire and the draw wire are solder-connected.

19. The solar cell module according to claim 11,
wherein the isolation member is formed to have a polygonal, circular or elliptic shape having an area larger than a solder wetting region at the portion where the extraction wire and the draw wire are solder-connected.

20. The solar cell module according to claim 8,
wherein the isolation member is configured to include a plurality of isolation members that are overlapped.

21. The solar cell module according to claim 9,
wherein the isolation member is configured to include a plurality of isolation members that are overlapped.

22. The solar cell module according to claim 10,
wherein the isolation member is configured to include a plurality of isolation members that are overlapped.

23. The solar cell module according to claim 11,
wherein the isolation member is configured to include a plurality of isolation members that are overlapped.

24. A method of manufacturing a solar cell module including a solar cell composed of a surface substrate, a light-receiving side conducting layer, a semiconductor layer and a back-side conducting layer and having a wiring structure in which an extraction wire for extraction of current is connected to the back-side conducting layer, and a draw wire for outputting the current to the outside is connected to the extraction wire, the method comprising the steps of:
disposing an isolation member on the back-side conducting layer of the solar cell corresponding to a portion where the extraction wire and the draw wire are to be connected; and
disposing a connection portion of the extraction wire on the disposed isolation member, disposing a connection portion of the draw wire on the connection portion in an overlapped manner, and electrically connecting the connection portion of the draw wire to the connection portion of the extraction wire.
